(19) United States
(12) Patent Application Publication
(10) Pub. No.: US 2021/0267090 A1
(43) Pub. Date: Aug. 26, 2021

(54) DISPLAY DEVICE

(71) Applicant: SHARP KABUSHIKI KAISHA, Osaka (JP)

(72) Inventor: HAYATO SAITO, Osaka (JP)

(21) Appl. No.: 17/010,738

(22) Filed: Sep. 2, 2020

Related U.S. Application Data
(60) Provisional application No. 62/981,764, filed on Feb. 26, 2020.

(51) Int. Cl. H05K 7/20; G02F 1/1333; H05K 5/00

(52) U.S. Cl. CPC H05K 7/20127; G02F 1/133385; H05K 7/20954; H05K 5/0017; G02F 1/133308

(57) ABSTRACT

In a display device, a flow path for an airstream that flows from a lower air vent toward an upper air vent along a circuit substrate, based on generated heat from a circuit component is defined so as to face a back surface of a display panel in a housing. The flow path is defined such that a sectional area of the flow path varies along the circuit substrate.

### BACKGROUND

### 1. Field

The present disclosure relates to a display device.

### 2. Description of the Related Art

Regarding a known liquid-crystal display device in which a circuit substrate is disposed on a back surface of a reflector of a direct backlight of a liquid-crystal panel, and ventilation holes are formed through a lower surface and an upper surface of a rear portion of a cabinet that contains the liquid-crystal panel, the circuit substrate is disposed on the back surface of the reflector so as to be substantially parallel to the reflector and there is a gap through which natural convection occurs, and the gap through which the natural convection occurs is located between the circuit substrate and a back wall of the cabinet (Japanese Unexamined Patent Application Publication No. 2005-84354 (published on Mar. 31, 2005)).

In the liquid-crystal display device, air is heated as the temperature of the surface of the circuit substrate increases and flows upward along the circuit substrate. Consequently, the natural convection occurs, and the heat of the circuit substrate is dissipated.

### SUMMARY

According to the above existing technique, however, the heat of the circuit substrate is dissipated by using an airstream based on a stack effect in which the direction of a path through which the air is exhausted via the ventilation hole in the upper surface is limited to an upward direction along the circuit substrate. Accordingly, there is a problem in that heat dissipation by using the airstream is not sufficient regarding the upper half of the circuit substrate, although the heat of the lower half of the circuit substrate can be dissipated by using the airstream.

It is desirable to provide a display device that can achieve sufficient heat dissipation due to the stack effect of natural convection even regarding the upper half of a circuit substrate.

A display device according to an aspect of the present disclosure includes a display panel that displays an image, a housing that contains the display panel, and a circuit substrate that includes a circuit component relative to an image signal corresponding to the image that is displayed by the display panel and that faces a back surface of the display panel. A lower air vent and an upper air vent are formed through a lower surface and an upper surface of the housing. A flow path for an airstream that flows from the lower air vent toward the upper air vent along the circuit substrate, based on generated heat from the circuit component is defined so as to face the back surface of the display panel in the housing. The flow path is defined such that a sectional area of the flow path varies along the circuit substrate.

### BRIEF DESCRIPTION OF THE DRAWINGS

FIG. 1 is a sectional view of a display device according to a first embodiment;

FIG. 2 illustrates a relationship between flow velocity and sectional area;

FIG. 3 is a sectional view of a display device in a comparative example;

FIG. 4 is a sectional view for a description of natural convection relative to the display device;

FIG. 5 is a perspective view of a circuit substrate for a display panel that is included in the display device;

FIG. 6 illustrates a back wall of a housing that contains the display panel;

FIG. 7 illustrates a bottom surface of the housing;

FIG. 8 is a sectional view in which obliqueness of a T-con substrate that is included in the circuit substrate is illustrated;

FIG. 9 illustrates the temperature distribution of the T-Con substrate;

FIG. 10 illustrates the temperature distribution of a T-Con substrate in the comparative example;

FIG. 11 illustrates a flow velocity vector around the T-Con substrate viewed in front of a surface of the T-Con substrate opposite the display panel;

FIG. 12 illustrates the flow velocity vector around the T-Con substrate viewed in front of a surface of the T-Con substrate that faces the display panel;

FIG. 13 illustrates the flow velocity vector around the T-Con substrate viewed in front of a surface of the T-Con substrate that faces the display panel;

FIG. 14 illustrates the temperature distribution of the T-Con substrate;

FIG. 15 illustrates the distribution of the flow velocity vector around the T-Con substrate viewed in front of the surface of the T-Con substrate opposite the display panel;

FIG. 16 is a side view in which the velocity vector of air around the T-Con substrate is illustrated;

FIG. 17 is a graph in which a relationship between an oblique angle of the T-Con substrate with respect to the display panel and the temperature of the T-Con substrate is illustrated;

FIG. 18 illustrates the temperature distribution of the T-Con substrate when the oblique angle is 0 degrees;

FIG. 19 illustrates the temperature distribution of the T-Con substrate when the oblique angle is 1 degree;

FIG. 20 illustrates the temperature distribution of the T-Con substrate when the oblique angle is 3 degrees;

FIG. 21 illustrates the temperature distribution of the T-Con substrate when the oblique angle is 5 degrees;

FIG. 22 illustrates the temperature distribution of the T-Con substrate when the oblique angle is 6 degrees;

FIG. 23 illustrates the temperature distribution of the T-Con substrate when the oblique angle is 7 degrees;

FIG. 24 illustrates the temperature distribution of the T-Con substrate when the oblique angle is 8 degrees;

FIG. 25 illustrates the temperature distribution of the T-Con substrate when the oblique angle is 9 degrees;

FIG. 26 illustrates the temperature distribution of the T-Con substrate when the oblique angle is 10 degrees;

FIG. 27 illustrates the temperature distribution of the circuit substrate when the oblique angle is 0 degrees;

FIG. 28 illustrates the temperature distribution of the circuit substrate when the oblique angle is 7 degrees;

FIG. 29 illustrates the temperature distribution of the circuit substrate in the cases where the oblique angle is 0 degrees and 7 degrees;

FIG. 30 is a sectional view in which relationships among the T-Con substrate, the display panel, and the housing are illustrated;

FIG. 31 illustrates the temperature distribution of the T-Con substrate when the T-Con substrate, the display panel, and the housing are used;

FIG. 32 is a sectional view in which relationships among the T-Con substrate, the display panel, and another housing are illustrated;

FIG. 33 illustrates the temperature distribution of the T-Con substrate when the T-Con substrate, the display panel, and the other housing are used;

FIG. 34 is a sectional view in which relationships among the T-Con substrate, a display panel, and a housing in the comparative example are illustrated;

FIG. 35 illustrates the temperature distribution of the T-Con substrate when the T-Con substrate, the display panel, and the housing are used;

FIG. 36 is a sectional view of a display device according to a modification to the first embodiment;

FIG. 37 is a sectional view of a structure for installing the circuit substrate;

FIG. 38 is a sectional view of a structure for installing a circuit substrate in the comparative example;

FIG. 39 is a sectional view of another structure for installing the circuit substrate;

FIG. 40 is a sectional view of another structure for installing the circuit substrate;

FIG. 41 is a sectional view of a display device according to a second embodiment;

FIG. 42 illustrates the temperature distribution of a T-Con substrate that is included in the display device; and

FIG. 43 is a sectional view of another display device according to the second embodiment.

### DESCRIPTION OF THE EMBODIMENTS

### First Embodiment

### Structure of Display Device 1

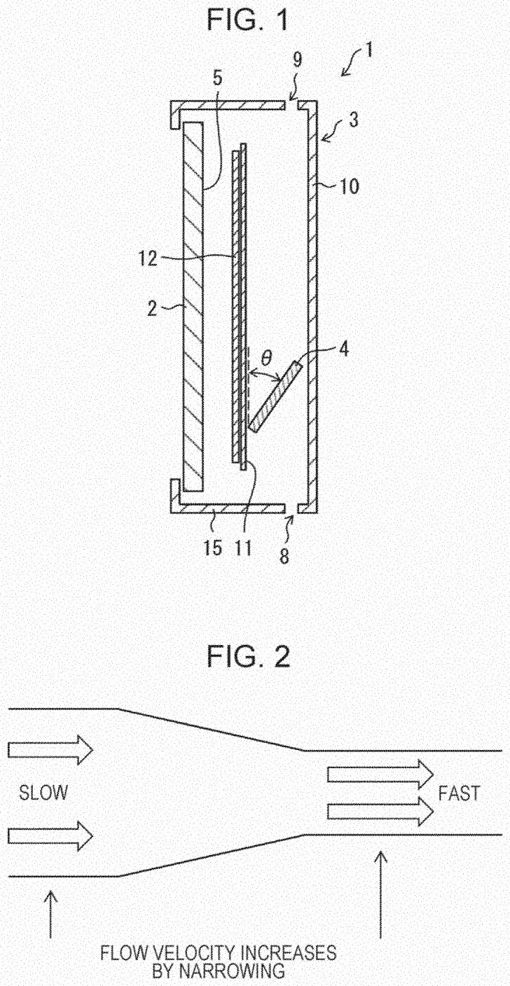

An embodiment of the present disclosure will now be described in detail. FIG. 1 is a sectional view of a display device 1 according to a first embodiment.

The display device 1 includes a display panel 2 that displays an image, a housing 3 that has, for example, a rectangular cuboid shape to contain the display panel 2, and a circuit substrate 4 that includes a circuit component relative to an image signal corresponding to the image that is displayed by the display panel 2 and that faces a back surface 5 of the display panel 2. A lower air vent 8 and an upper air vent 9 are formed through the lower surface and the upper surface of the housing 3. The upper air vent 9 is formed right above the lower air vent 8. The lower air vent 8 is formed below the circuit substrate 4. The upper air vent 9 is formed above the circuit substrate 4.

In an example described above, the upper air vent 9 is formed through the upper surface of the housing 3. The present disclosure, however, is not limited thereto. Provided that the upper air vent 9 is formed in an upper portion of the housing 3, the upper air vent 9 may be formed, for example, through an upper part of the back surface of the housing 3. The upper part of the back surface means a part that is located above a position at which the circuit substrate 4 is disposed. In the example described above, the lower air vent 8 is formed through the lower surface of the housing 3. The present disclosure, however, is not limited thereto. Provided that the lower air vent 8 is formed in a lower portion of the housing 3, the lower air vent 8 may be formed, for example, through a lower part of the back surface of the housing 3. The lower part of the back surface means a part that is located below a position at which the circuit substrate 4 is disposed.

In the example described above, the housing 3 has a rectangular cuboid shape. The present disclosure, however, is not limited thereto. Provided that the housing 3 has a shape suitable to contain, for example, the display panel 2, the housing 3 may have, for example, a shape that contains no upper surface. The display device 1 may be a television receiver (commonly known as a television) that receives a radio wave of television broadcasting and that is used to display (watch and listen) an image and a sound, or a display or a monitor that displays an image signal of a still image or a moving image that is outputted from a device such as a computer. In an example described herein, the display panel 2 is a liquid-crystal display panel but may be an organic EL (Electro-Luminescence) display panel or a plasma display panel. The circuit substrate 4 includes, for example, a timing controller substrate (T-Con substrate) that converts the image signal into a panel drive signal and that transmits the panel drive signal to display elements that are arranged in the display panel 2.

In the housing 3, a backlight portion 12 that irradiates the display panel 2 with backlight and a support chassis 11 that includes a metal frame that secures the backlight portion 12 and the circuit substrate 4 are disposed between the display panel 2 and the circuit substrate 4.

Based on generated heat from the circuit component that is included in the circuit substrate 4, air in contact with the circuit substrate 4 is heated and flows upward toward the upper air vent 9, and air enters from the outside via the lower air vent 8. Consequently, a flow path for an airstream that flows from the lower air vent 8 toward the upper air vent 9 along the circuit substrate 4 is defined so as to face the back surface 5 of the display panel 2 in the housing 3. The flow path is defined such that a sectional area of the flow path varies along the circuit substrate 4.

In an example illustrated in FIG. 1, the circuit substrate 4 is oblique at an oblique angle θ with respect to the back surface 5 of the display panel 2. Consequently, the sectional area of the flow path for the airstream that flows from the lower air vent 8 toward the upper air vent 9 along the circuit substrate 4 varies along the circuit substrate 4.

As illustrated in FIG. 1, the circuit substrate 4 may be oblique with respect to the back surface of the display panel 2 such that the distance between a portion of the circuit substrate that faces the lower air vent 8 and the back surface 5 of the display panel 2 is shorter than the distance between a portion of the circuit substrate that faces the upper air vent 9 and the back surface 5 of the display panel 2. Consequently, the circuit substrate 4 is oblique at the oblique angle θ with respect to the back surface 5 of the display panel 2. The oblique angle θ may be no less than 3 degrees and no more than 7 degrees, for example, when satisfying a condition of a simulation described later. A preferably angle changes depending on the condition of the simulation.

FIG. 2 illustrates a relationship between flow velocity and the sectional area. The sectional area of the flow path for the airstream that flows from the lower air vent 8 toward the upper air vent 9 along the circuit substrate 4, based on the generated heat from the circuit component that is included in the circuit substrate 4 varies along the circuit substrate 4. The flow velocity of the airstream and the sectional area of the flow path through which the airstream flows satisfy

Flow Rate (m³/second)=Sectional Area (m²)×Flow Velocity (m/second). When the flow rate is fixed, the sectional area and the flow velocity are in inverse proportion to each other. That is, as illustrated in FIG. 2, as the flow path through which the airstream flows is narrowed, and the sectional area of the flow path decreases, the flow velocity of the airstream increases.

Accordingly, the flow velocity of the airstream that flows from the lower air vent 8 toward the upper air vent 9 along the circuit substrate 4, based on the generated heat from the circuit component that is included in the circuit substrate 4 increases in a region in which the sectional area of the flow path decreases between a back wall 10 of the housing 3 and the substrate 4 that is oblique at the oblique angle θ near the portion that faces the upper air vent 9 and in a region in which the sectional area of the flow path decreases between the support chassis 11 and the substrate 4 that is oblique at the oblique angle θ near the portion that faces the lower air vent 8.

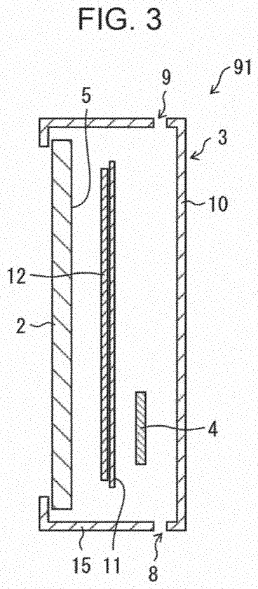

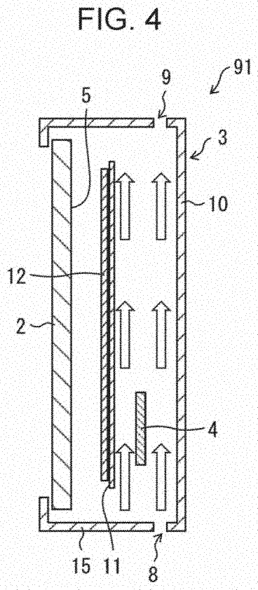

FIG. 3 is a sectional view of a display device 91 in a comparative example. FIG. 4 is a sectional view for a description of natural convection relative to the display device 91. Components like to the above components are designated by like reference characters, and a detailed description thereof is not repeated.

The circuit substrate 4 of the display device 91 is parallel to the back surface 5 of the display panel 2. Air that is heated by the circuit substrate 4 that generates heat becomes an airstream and flows upward, and air in an amount corresponding to the amount of the air that flows upward enters the housing 3 via the lower air vent 8. Consequently, natural convection occurs in the direction from the lower air vent 8 toward the upper air vent 9 between the circuit substrate 4 and the back wall 10 of the housing 3 and between the circuit substrate 4 and the support chassis 11.

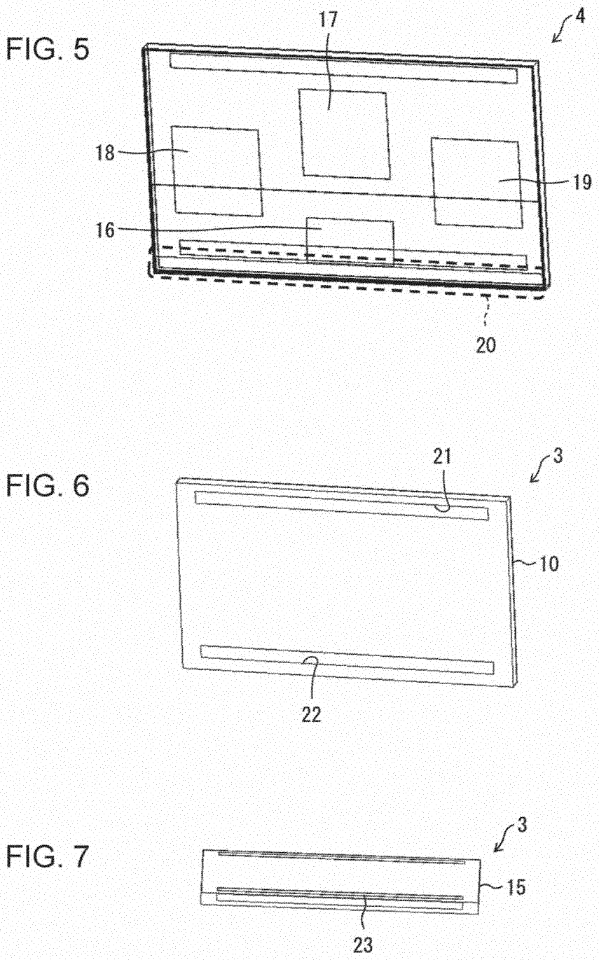

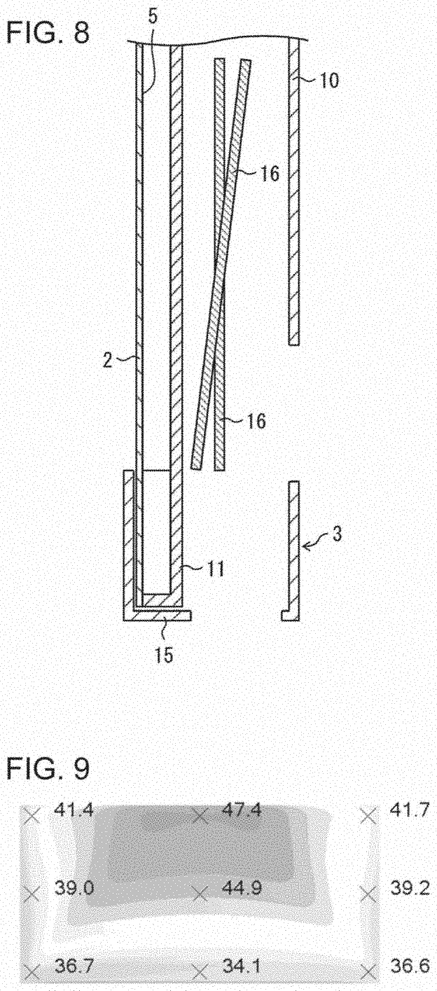

FIG. 5 is a perspective view of the circuit substrate 4 for the display panel 2 that is included in the display device 1. FIG. 6 illustrates the back wall 10 of the housing 3 that contains the display panel 2. FIG. 7 illustrates a bottom surface 15 of the housing 3. FIG. 8 is a sectional view in which obliqueness of a T-con substrate 16 that is included in the circuit substrate 4 is illustrated. Components like to the above components are designated by like reference characters, and a detailed description thereof is not repeated.

The heat dissipation of the circuit substrate 4 according to the first embodiment is verified by performing a simulation. FIG. 5 to FIG. 8 illustrate conditions of the simulation that is performed by way of example.

The circuit substrate 4 includes the T-Con substrate 16 that converts the image signal into the panel drive signal, that transmits the panel drive signal to the display elements of the display panel 2, and that has a power consumption of about 10 W, a LED driver substrate 17 that controls power of a LED that is a light source of the backlight portion 12 and that has a power consumption of about 30 W, a power supply substrate 18 that supplies power to the entire display device 1 and that has a power consumption of about 20 W, a first substrate 19 that controls the entire display device 1, that performs single processing, and that has a power consumption of about 10 W, and an edge LED substrate 20 that is disposed on a side surface portion, that is a LED substrate serving as a backlight source, and that has a power consumption of about 216 W in a liquid-crystal method in which light is emitted in a direction of a side surface of the display panel 2. Heat dissipation holes 21 and 22 that are long holes are formed in the back wall 10 of the housing 3. The heat dissipation hole 21 is a specific example of the upper air vent 9 illustrated in, for example, FIG. 1. The heat dissipation hole 22 is a specific example of the lower air vent 8 illustrated in, for example, FIG. 1. A heat dissipation hole 23 that is a long hole is formed in the bottom surface 15 of the housing 3. The heat dissipation hole 23 is a specific example of the lower air vent 8.

The heat dissipation hole 21 is formed above the circuit substrate 4 that faces the back surface 5 of the display panel 2. The heat dissipation hole 22 and the heat dissipation hole 23 are formed below the circuit substrate 4.

### Effects of Display Device 1

Comparison is performed between simulation results of the heat dissipation in the case where the T-Con substrate 16 that generates heat is parallel to the back surface 5 of the display panel 2 and in the case where the T-Con substrate 16 is oblique at 7 degrees with respect to the back surface 5 of the display panel 2.

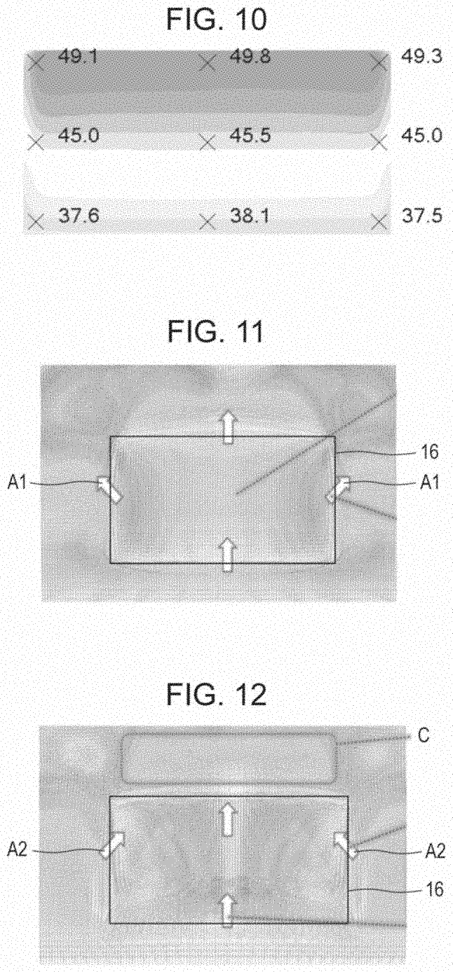

FIG. 9 illustrates the temperature distribution of the T-Con substrate 16. FIG. 10 illustrates the temperature distribution of the T-Con substrate in the comparative example. FIG. 11 illustrates a flow velocity vector around the T-Con substrate 16 viewed in front of a surface of the T-Con substrate 16 opposite the display panel 2. FIG. 12 illustrates the flow velocity vector around the T-Con substrate 16 viewed in front of a surface of the T-Con substrate 16 that faces the display panel 2.

In a region opposite the display panel 2, the air that flows upward is impeded by the T-Con substrate 16 that is oblique. Accordingly, as the air flows upward along the T-Con substrate 16, the magnitude and density of the flow velocity vector increases. As illustrated by arrows A1 in FIG. 11, the airstream hits the T-Con substrate 16 and passes from the sides of the T-Con substrate 16 so as to be along the T-Con substrate 16. As illustrated by arrows A2 in FIG. 12, the air flows toward the surface of the T-Con substrate 16 that faces the display panel 2. The airstream dissipates the heat of the T-Con substrate 16 while flowing along the T-Con substrate 16, and the heat dissipation is improved regarding edges of an upper portion of the T-Con substrate 16. For example, as illustrated in FIG. 10, the temperature of an upper left edge of the T-Con substrate in the comparative example is about 49.1° C., and the temperature of an upper right edge thereof is about 49.3° C. As illustrated in FIG. 9, however, the temperature of an upper left edge of the T-Con substrate 16 according to the first embodiment decreases to about 41.4° C., and the temperature of an upper right edge thereof decreases to about 41.7° C.

Near the lower edge of the T-Con substrate 16 that faces the display panel 2, the sectional area of the flow path sharply decreases, and the flow velocity sharply increases. The air the flow velocity of which sharply increases flows upward along the T-Con substrate 16, and the density of the air along the surface of the T-Con substrate 16 that faces the display panel 2 decreases. Accordingly, as illustrated by the arrows A2, the air flows thereto from the surface of the T-Con substrate 16 opposite the display panel 2. On an upper portion C of the T-Con substrate 16, the flow velocity increases.

It can be said from the above description that, in the case where the T-Con substrate 16 that generates heat is oblique, the flow of the air can be controlled, and that the heat dissipation is better than that in the case where the T-Con substrate is parallel to the display panel 2.

In particular, in the case where the T-Con substrate 16 is oblique, airstream toward the opposite surface is produced along left and right edges of the T-Con substrate 16, and the efficiency of the heat dissipation regarding the left and right edges of the upper portion of the T-Con substrate is greatly improved, although the heat thereof is conventionally difficult to be dissipated.

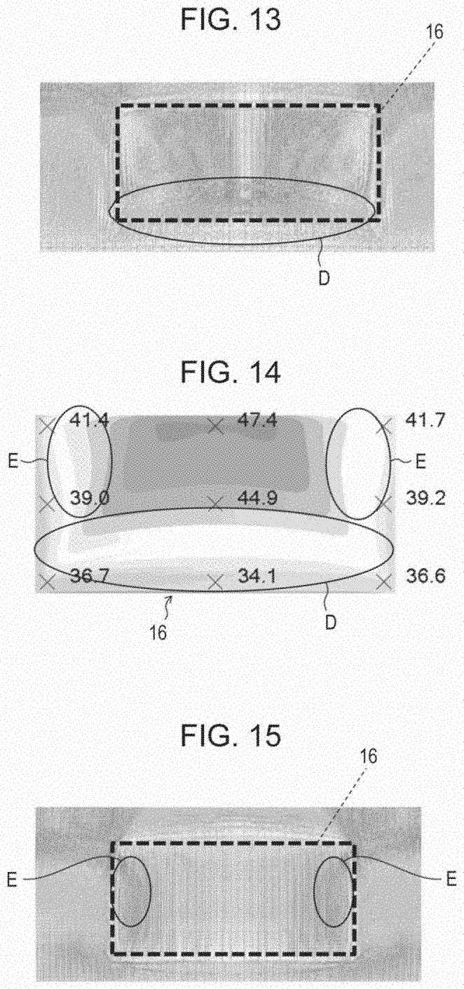

FIG. 13 illustrates the flow velocity vector around the T-Con substrate 16 viewed in front of the surface of the T-Con substrate 16 that faces the display panel 2. FIG. 14 illustrates the temperature distribution of the T-Con substrate 16. FIG. 15 illustrates the distribution of the flow velocity vector around the T-Con substrate 16 viewed in front of the surface of the T-Con substrate 16 opposite the display panel 2.

In a lower region D of the T-Con substrate 16 that faces the display panel 2, the sectional area of the flow path for the air sharply decreases, and the flow velocity increases. Subsequently, the flow velocity gradually decreases. At this time, as illustrated in FIG. 14, the heat dissipation in the lower region D of the T-Con substrate 16 is improved due to the influence of the flow velocity.

In left and right regions E of the T-Con substrate 16, the air flows toward the surface of the T-Con substrate 16 that faces the display panel 2 from the surface of the T-Con substrate 16 opposite the display panel 2 due to the obliqueness of the T-Con substrate 16 as described above. As a result of this influence, as illustrated in FIG. 14, the heat dissipation in the left and right regions E of the T-Con substrate 16 is improved.

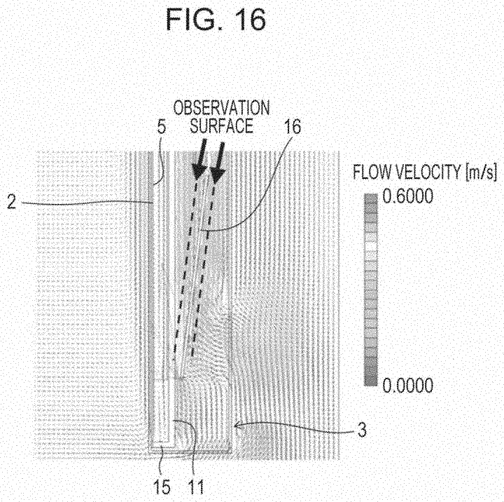

FIG. 16 is a side view in which the velocity vector of the air around the T-Con substrate 16 is illustrated. The air that flows upward along the surface of the T-Con substrate 16 opposite the display panel 2 is impeded by the T-Con substrate 16 that is oblique, and airstream that passes from the sides of the T-Con substrate 16 is produced. The air flows toward the surface of the T-Con substrate 16 that faces the display panel 2, and the heat dissipation is improved regarding the edges of the upper portion of the T-Con substrate 16.

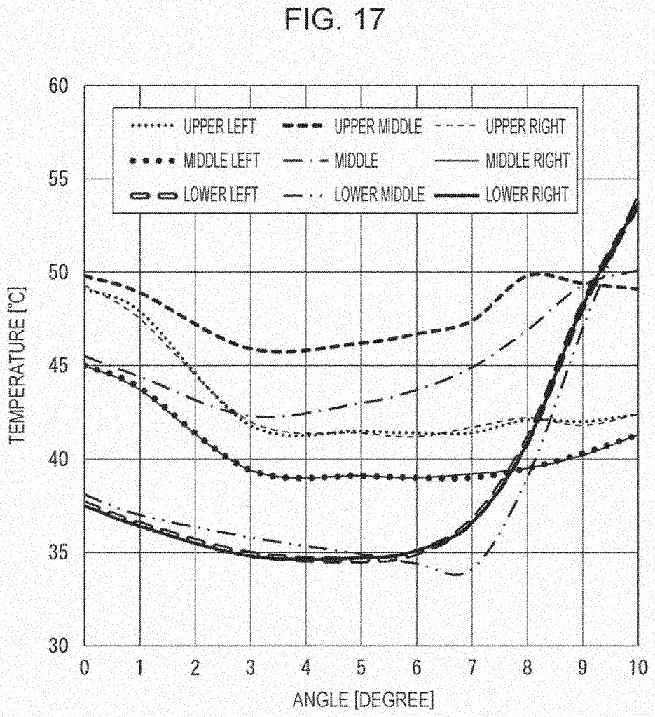

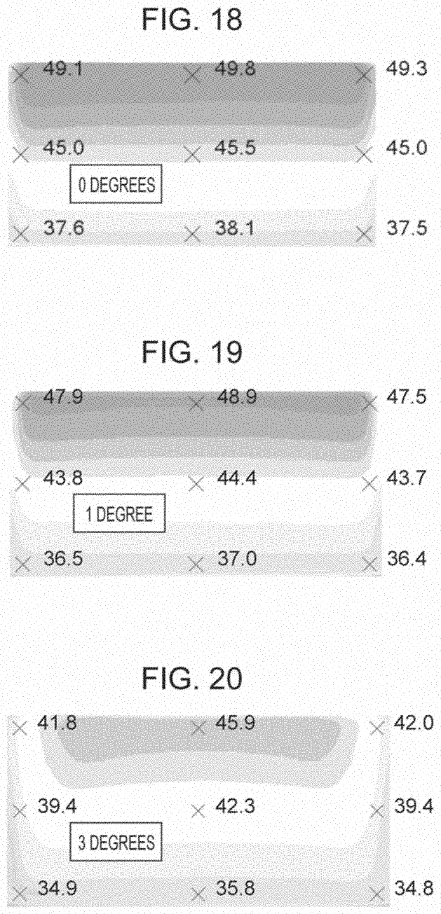

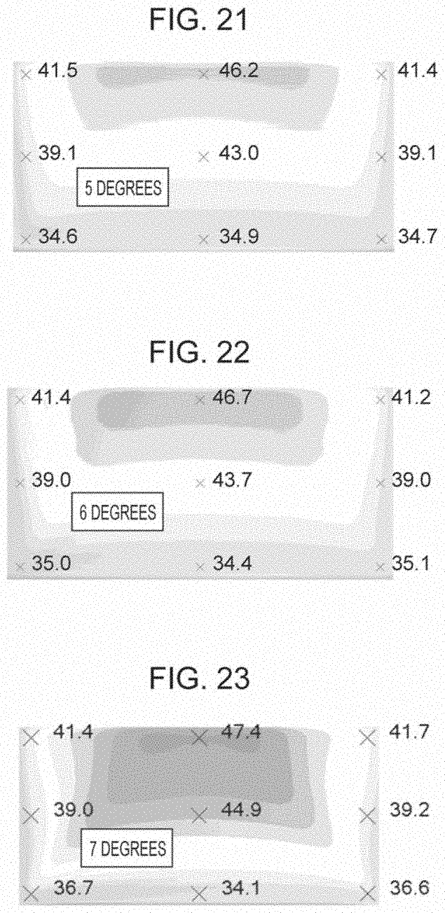

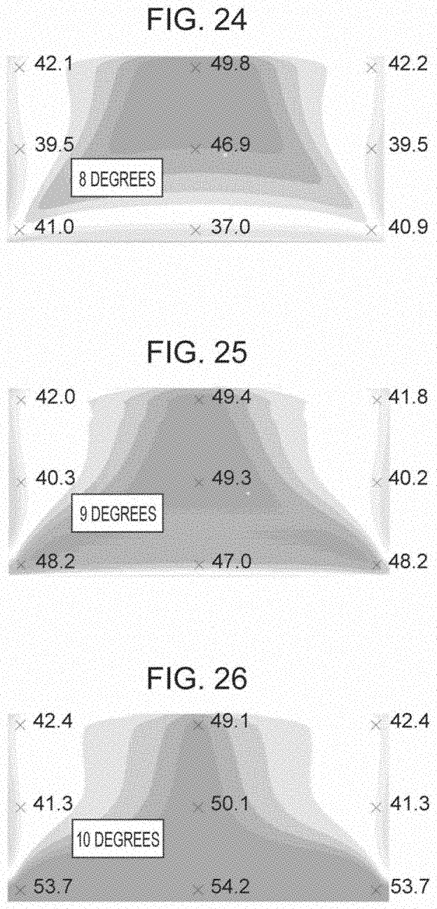

FIG. 17 is a graph in which a relationship between the oblique angle of the T-Con substrate 16 with respect to the display panel 2 and the temperature of the T-Con substrate 16 is illustrated. FIG. 18 to FIG. 26 illustrate the temperature distribution of the T-Con substrate 16 in the cases where the oblique angle ranges from 0 degrees to 10 degrees.

A change in the degree of the heat dissipation due to a change in the oblique angle of the T-Con substrate 16 is simulated to verify the influence of the oblique angle on the heat dissipation. In the case where the T-Con substrate 16 is oblique, the heat dissipation is improved as described above. The result of verification about the optimum angle will now be described.

The optimum oblique angle of the T-Con substrate 16 changes depending on a point at which heat is to be especially dissipated, and the point is selected from the upper left, the middle left, the lower left, the upper middle, the middle, the lower middle, the upper right, the middle right, and the lower right of the T-Con substrate 16. Overall, it is considered that the heat is more efficiently dissipated when the oblique angle is between 3 degrees and 5 degrees as illustrated in FIG. 17.

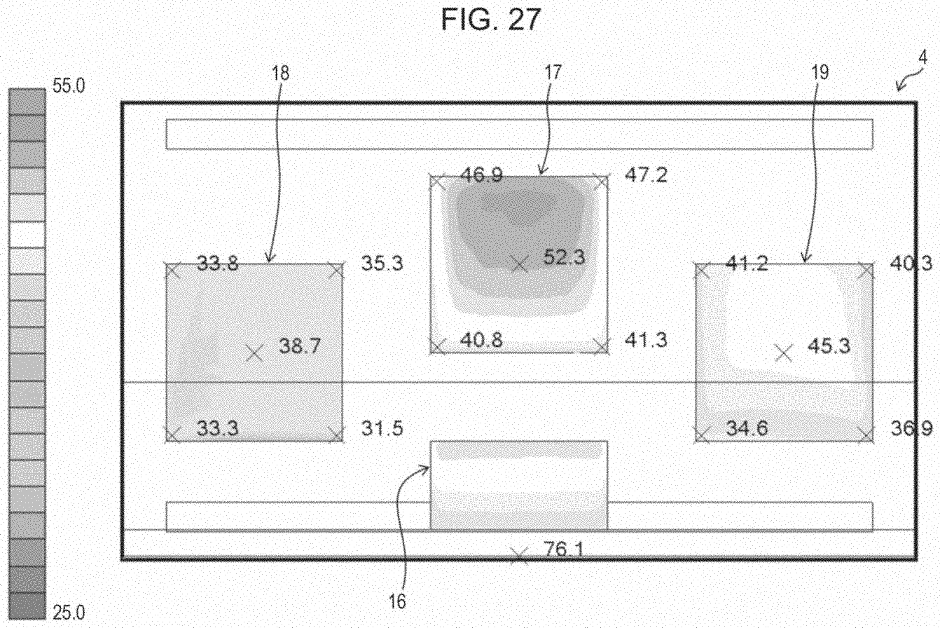

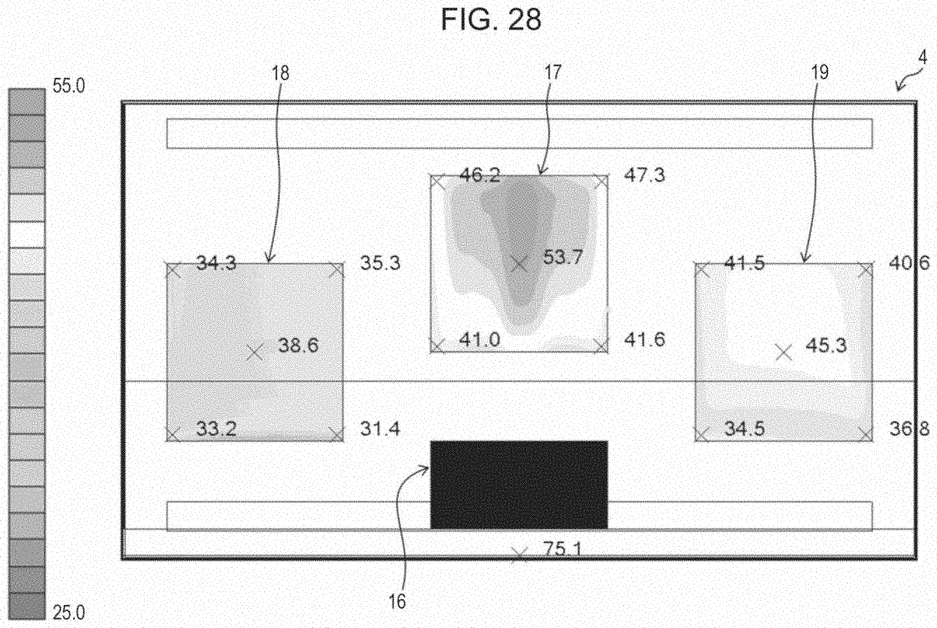

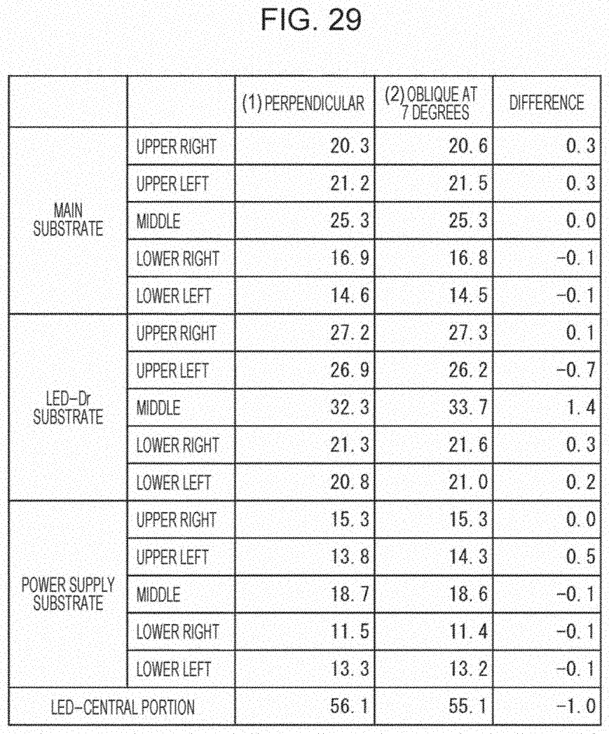

FIG. 27 illustrates the temperature distribution of the circuit substrate 4 when the oblique angle is 0 degrees. FIG. 28 illustrates the temperature distribution of the circuit substrate 4 when the oblique angle is 7 degrees. FIG. 29 illustrates the temperature distribution of the circuit substrate 4 in the cases where the oblique angle is 0 degrees and 7 degrees.

With only the T-Con substrate 16 of the circuit substrate 4 being oblique at 7 degrees, influence on the LED driver substrate 17, the power supply substrate 18, and the first substrate 19 that are not oblique except for the T-Con substrate 16 of the circuit substrate 4 is checked. As illustrated in FIG. 28, it is seen that the temperature of a central portion of the LED driver substrate 17 that is located right above the T-Con substrate 16 relatively becomes worse. As illustrated in FIG. 29, however, it is an increase by about +1.4° C., and the influence is not strong. Other than this, the influence is sufficiently weak.

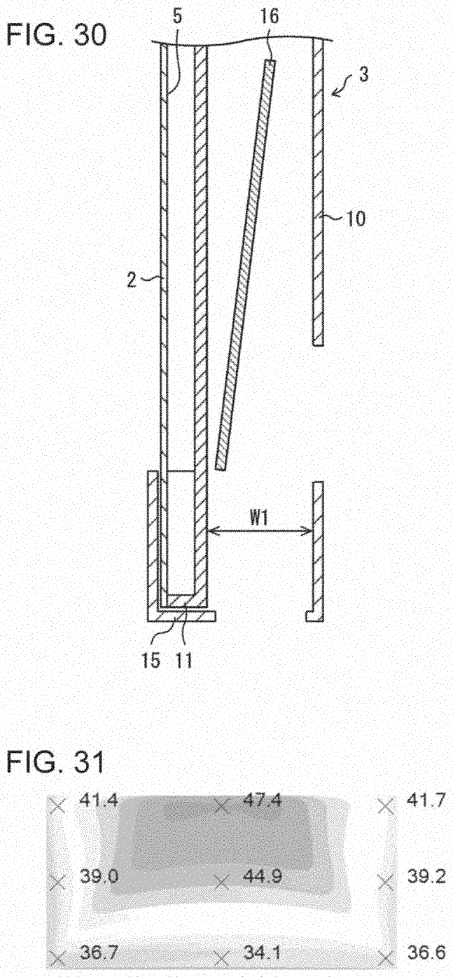

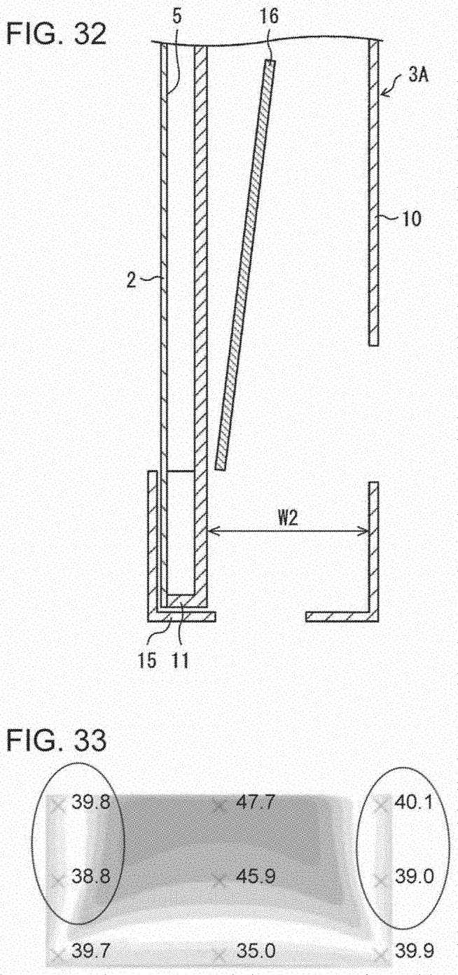

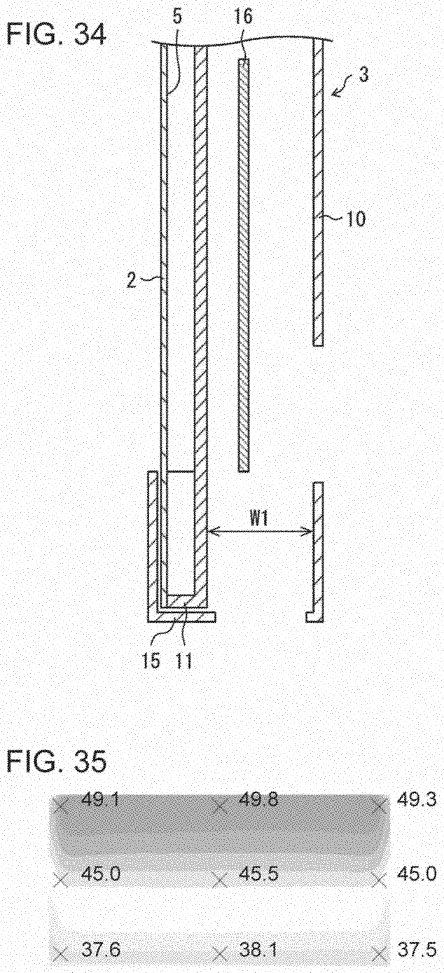

FIG. 30 is a sectional view in which relationships among the T-Con substrate 16, the display panel 2, and the housing 3 are illustrated. FIG. 31 illustrates the temperature distribution of the T-Con substrate 16 when the T-Con substrate 16, the display panel 2, and the housing 3 are used. FIG. 32 is a sectional view in which relationships among the T-Con substrate 16, the display panel 2, and another housing 3A are illustrated. FIG. 33 illustrates the temperature distribution of the T-Con substrate 16 when the T-Con substrate 16, the display panel 2, and the housing 3A are used. FIG. 34 is a sectional view in which relationships among the T-Con substrate, the display panel 2, and the housing 3 in the comparative example are illustrated. FIG. 35 illustrates the temperature distribution of the T-Con substrate when the T-Con substrate, the display panel 2, and the housing 3 in the comparative example are used.

The influence of a width with which the circuit substrate 4 is installed on the improvement in the heat dissipation in the case where the T-Con substrate 16 has the oblique angle is checked.

As illustrated in FIG. 30, the T-Con substrate 16 that is installed so as to be oblique in the housing 3 that has a width W1 between the inner surface of the back wall 10 and the support chassis 11. As illustrated in FIG. 32, the T-Con substrate 16 is installed so as to be oblique in the housing 3A that has a width W2 greater than the width W1. As illustrated in FIG. 34, the T-Con substrate 16 is installed so as to be parallel to the display panel 2 in the housing 3 that has the width W1. As illustrated in FIG. 31, FIG. 33, and FIG. 35, the temperature of the T-Con substrate 16 is simulated.

As illustrated in FIG. 31 and FIG. 33, the same degree of the heat dissipation is achieved even when the width with which the T-Con substrate 16 is installed changes, and the temperatures of upper left and upper right portions of the T-Con substrate 16 effectively decrease. However, in the case where the T-Con substrate 16 is installed so as to be oblique in the housing 3A that has the width W2 greater than the width W1, the degree of the variation in the sectional area of the flow path through which the air flows is less than that in the case of the width W1, and the degree of the heat dissipation decreases when the width W2 is too great compared with the case of the width W1.

### Modification to First Embodiment

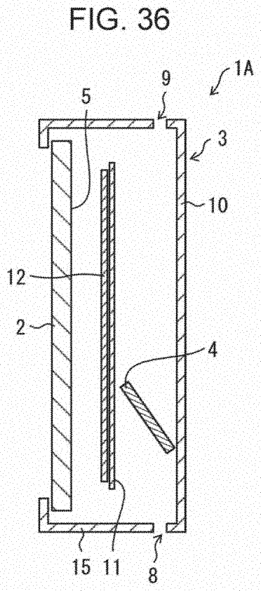

FIG. 36 is a sectional view of a display device 1A according to a modification to the first embodiment. Components like to the above components are designated by like reference characters, and a detailed description thereof is not repeated.

As illustrated in FIG. 36, the circuit substrate 4 may be oblique with respect to the back surface of the display panel 2 such that the distance between a portion of the circuit substrate that faces the lower air vent 8 and the back surface 5 of the display panel 2 is longer than the distance between a portion of the circuit substrate that faces the upper air vent 9 and the back surface 5 of the display panel 2, on the contrary to the structure illustrated in FIG. 1. Also, with this structure, the same effects as described above are achieved.

### Structure for Installing Circuit Substrate 4

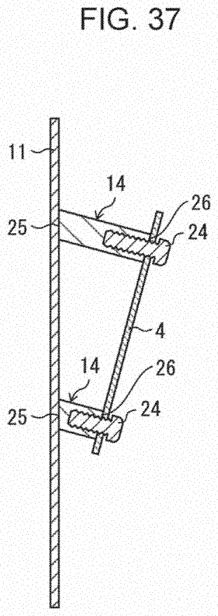

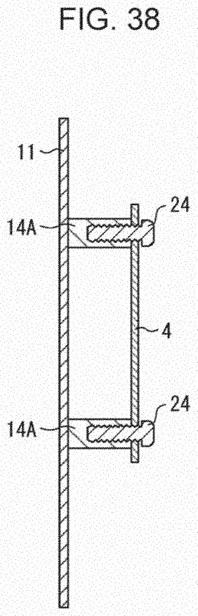

FIG. 37 is a sectional view of a structure for installing the circuit substrate 4. FIG. 38 is a sectional view of a structure for installing the circuit substrate 4 in the comparative example. Components like to the above components are designated by like reference characters, and a detailed description thereof is not repeated.

As illustrated in FIG. 37, substantially cylindrical boss members 14 that are used to dispose the circuit substrate 4 obliquely with respect to the display panel 2 have tapped holes that extend along the central axis and that are formed through end surfaces 26. Other end surfaces 25 are oblique with respect to the central axis such that the circuit substrate 4 is oblique. The end surfaces 25 of the boss members 14 are mounted on the support chassis 11. The circuit substrate 4 is secured to the end surfaces 26 of the boss members 14 so as to be oblique with respect to the display panel 2 by using screws 24.

As illustrated in FIG. 38, cylindrical boss members 14A that are used to dispose the circuit substrate 4 parallel to the display panel 2 have tapped holes that extend along the central axis and that are formed through end surfaces. Other end surfaces are perpendicular to the central axis. The circuit substrate 4 is secured to the end surfaces of the boss members 14A so as to be parallel to the display panel 2 by using the screws 24.

Thus, the support chassis 11 that faces the back surface 5 of the display panel 2 is disposed to support the display panel 2, and the boss members 14 that face the surface of the support chassis 11 opposite the display panel 2 are disposed to support the circuit substrate 4. The boss members 14 have the tapped holes that extend along the central axis and that are used to mount the circuit substrate 4 on the boss members 14. The end surfaces 25 that face the support chassis 11 are oblique with respect to the central axis depending on the oblique angle of the circuit substrate 4.

With this structure in FIG. 37, time and effort for installing the circuit substrate 4 do not differ from those for installation in the comparative example, which is an advantage.

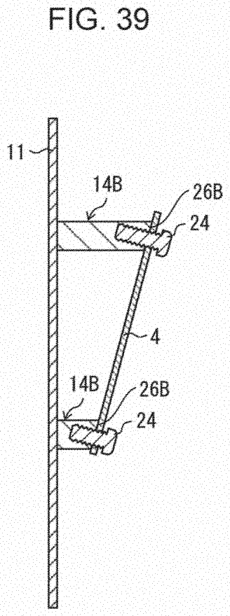

FIG. 39 is a sectional view of another structure for installing the circuit substrate 4. Components like to the above components are designated by like reference characters, and a detailed description thereof is not repeated.

Substantially cylindrical boss members 14B are used to dispose the circuit substrate 4 obliquely. As illustrated in FIG. 39, the boss members 14B have end surfaces 26B that are oblique with respect to the central axis such that the circuit substrate 4 is oblique. The tapped holes are perpendicular to the end surfaces 26B. The boss members 14B are mounted perpendicularly to the support chassis 11. The circuit substrate 4 is installed on the end surfaces 26B by using the screws 24 so as to be oblique with respect to the display panel 2.

The boss members 14B thus have the tapped holes that are used to mount the circuit substrate 4 on the boss members 14B. The end surfaces 26B that face the circuit substrate 4 are oblique with respect to the central axis depending on the oblique angle of the circuit substrate 4.

With this structure in FIG. 39, time and effort for installing the circuit substrate 4 do not differ from those for installation in the comparative example, which is an advantage.

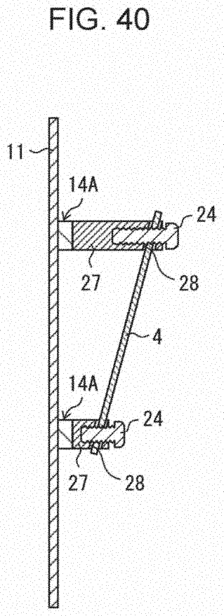

FIG. 40 is a sectional view of another structure for installing the circuit substrate 4. Components like to the above components are designated by like reference characters, and a detailed description thereof is not repeated.

Oblique members 27 that have tapped holes that extend along the central axis and that are formed through end surfaces 28 that are oblique with respect to the central axis are added to the boss members 14A. The circuit substrate 4 is obliquely installed such that the circuit substrate 4 is sandwiched by using the screws 24.

On the boss members 14A, there are the oblique members 27 in which the tapped holes that are used to mount the circuit substrate 4 are formed along the central axis through the end surfaces 28 that face the circuit substrate 4 and that are oblique with respect to the central axis depending on the oblique angle of the circuit substrate 4.

With this structure in FIG. 40, enlarging the tapped holes of the circuit substrate 4 for the screws 24 enables the screws 24 to be secured perpendicularly to the support chassis 11.

### Effects According to First Embodiment

According to the first embodiment described above, the flow path for the airstream that flows from the lower air vent 8 toward the upper air vent 9 along the circuit substrate 4, based on the generated heat from the circuit component is defined so as to face the back surface 5 of the display panel 2 in the housing 3. The flow path is defined such that the sectional area of the flow path varies along the circuit substrate 4. Accordingly, in a region of the flow path near the upper half of the circuit substrate 4 where the sectional area is narrowed, the flow velocity of the airstream increases, and the heat dissipation of the circuit component that generates heat is facilitated. Consequently, sufficient heat dissipation due to the stack effect of the natural convection can be achieved even regarding the upper half of the circuit substrate.

### Second Embodiment

Another embodiment of the present disclosure will now be described. For convenience of description, components that have the same functions as those of the components described according to the above embodiment are designated by like reference numbers, and a description thereof is not repeated.

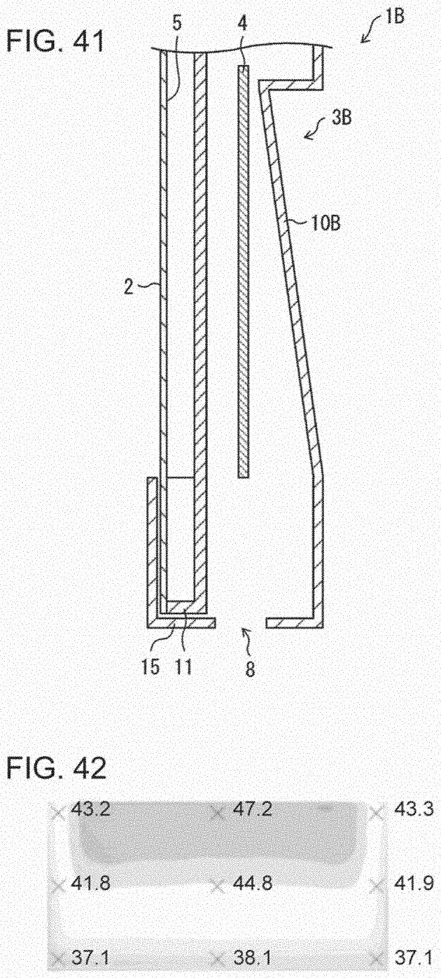

FIG. 41 is a sectional view of a display device 1B according to a second embodiment. FIG. 42 illustrates the temperature distribution of a T-Con substrate that is included in the display device 1B. Components like to the above components are designated by like reference characters, and a detailed description thereof is not repeated.

According to the above first embodiment, the circuit substrate 4 is oblique. The present disclosure, however, is not limited thereto, provided that the sectional area of the flow path for the airstream that flows from the lower air vent 8 toward the upper air vent 9 along the circuit substrate 4, based on the generated heat from the circuit component varies along the circuit substrate 4. For example, as illustrated in FIG. 41, the circuit substrate 4 may be parallel to the display panel 2, and a back wall 10B of a housing 3B may be oblique such that the flow path for the airstream is narrowed.

The back wall 10B described herein means a side wall that faces the back surface 5 of the display panel 2 among the side walls of the housing 3B.

The back wall 10B of the housing 3B that faces the back surface 5 of the display panel 2 is thus oblique inward toward the back surface 5 of the display panel 2. The back wall 10B may be formed such that the flow path becomes narrower as the position is closer to the upper air vent 9 from the lower air vent 8 along the circuit component. Consequently, the sectional area of the flow path between the circuit substrate 4 and the back wall 10B gradually decreases in the upward direction, and the flow velocity increases. This enables the heat dissipation to be better than that in the case of an existing structure.

With this structure, a method of installing the circuit substrate 4 may not be changed, and introduction becomes easy. Accordingly, sufficient heat dissipation is achieved, and operation is easy.

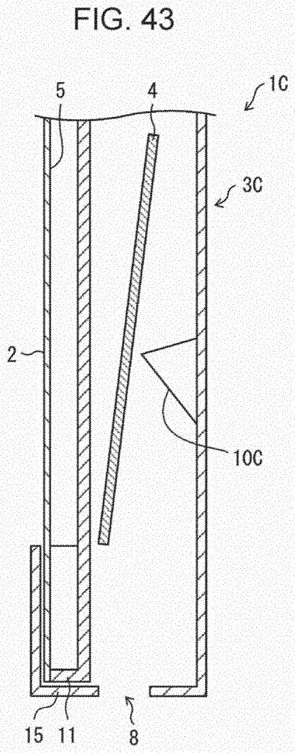

FIG. 43 is a sectional view of a display device 1C according to the second embodiment. Components like to the above components are designated by like reference characters, and a detailed description thereof is not repeated.

As illustrated in FIG. 43, the circuit substrate 4 may be oblique, and a back wall 10C of a housing 3C may be oblique.

According to the second embodiment described above, the back walls 10B and 10C of the housings 3B and 3C that face the back surface 5 of the display panel 2 may be oblique with respect to the back surface 5 of the display panel 2. Accordingly, the sectional area of the flow path for the airstream that flows from the lower air vent 8 toward the upper air vent 9 along the circuit substrate 4, based on the generated heat from the circuit component can vary along the circuit substrate 4.

### SUMMARY

The display device 1, 1A, 1B, 1C according to a first aspect of the present disclosure includes the display panel 2 that displays an image, the housing 3, 3B, 3C that contains the display panel 2, and the circuit substrate 4 that includes the circuit component relative to an image signal corresponding to the image that is displayed by the display panel 2 and that faces the back surface 5 of the display panel 2. The housing 3, 3B, 3C has the lower air vent 8 that is formed below the circuit substrate 4 and the upper air vent 9 that is formed above the circuit substrate 4. The flow path for the airstream that flows from the lower air vent 8 toward the upper air vent 9 along the circuit substrate 4, based on the generated heat from the circuit component is defined so as to face the back surface 5 of the display panel 2 in the housing 3, 3B, 3C. The flow path is defined such that the sectional area of the flow path varies along the circuit substrate 4.

With the above structure, in the region of the flow path near the upper half of the circuit substrate where the sectional area is narrowed, the flow velocity of the airstream increases, and the heat dissipation of the circuit component that generates heat is facilitated. Consequently, sufficient heat dissipation due to the stack effect of the natural convection can be achieved even regarding the upper half of the circuit substrate as in the lower half.

In the display device 1, 1A, 1C according to a second aspect of the present disclosure, the circuit substrate 4 may be oblique with respect to the back surface 5 of the display panel 2 in the above first aspect.

With the above structure, since the circuit substrate is oblique, the sectional area of the flow path for the airstream that flows from the lower air vent toward the upper air vent along the circuit substrate, based on the generated heat from the circuit component can vary along the circuit substrate.

In the display device 1, 1C according to a third aspect of the present disclosure, the circuit substrate 4 may be oblique such that the distance between the portion of the circuit substrate that faces the lower air vent 8 and the back surface 5 of the display panel 2 is shorter than the distance between the portion of the circuit substrate that faces the upper air vent 9 and the back surface 5 of the display panel 2 in the above second aspect.

With the above structure, the circuit substrate can be oblique with respect to the back surface of the display panel.

In the display device 1, 1A, 1C according to a fourth aspect of the present disclosure, the oblique angle of the circuit substrate 4 with respect to the back surface 5 of the display panel 2 may be no less than 3 degrees and no more than 7 degrees in the above second aspect.

With the above structure, when the oblique angle is 3 degrees or more, the heat of the entire circuit substrate can be efficiently dissipated. When the oblique angle is 7 degrees or less, the display device can be compact in the depth dimension.

In the display device 1B, 1C according a fifth aspect of the present disclosure, the back wall 10B, 10C of the housing 3B, 3C that faces the back surface 5 of the display panel 2 may be formed so as to be oblique with respect to the back surface 5 of the display panel 2 in the above first aspect.

With the above structure, the back wall of the housing that faces the back surface of the display panel may be oblique with respect to the back surface of the display panel. Accordingly, the sectional area of the flow path for the airstream that flows from the lower air vent toward the upper air vent along the circuit substrate, based on the generated heat from the circuit component can vary along the circuit substrate.

In the display device 1B, 1C according to a sixth aspect of the present disclosure, the back wall 10B, 10C may be formed such that the flow path becomes narrower as the position is closer to the upper air vent 9 from the lower air vent 8 along the circuit substrate 4 in the above fifth aspect.

With the above structure, the back wall of the housing that faces the back surface of the display panel can be oblique with respect to the back surface of the display panel.

The display device 1, 1A, 1C according to a seventh aspect of the present disclosure may further include the support chassis 11 that supports the display panel 2 and that faces the back surface 5 of the display panel 2, and the boss member 14, 14B that supports the circuit substrate 4 and that face the surface of the support chassis 11 opposite the display panel 2 in the above second aspect.

With the above structure, the circuit substrate can be oblique with respect to the back surface of the display panel.

In the display device 1, 1A, 1C according to an eighth aspect of the present disclosure, the boss member 14 may have the tapped hole that is used to mount the circuit substrate 4 on the boss member 14 and that extends along the central axis, and the end surface 25 thereof that faces the support chassis 11 may be oblique with respect to the central axis depending on the oblique angle of the circuit substrate 4 in the above seventh aspect.

With the above structure, the circuit substrate can be oblique with respect to the back surface of the display panel.

In the display device 1, 1A, 1C according to a ninth aspect of the present disclosure, the boss member 14B may have the tapped hole that is used to mount the circuit substrate 4 on the boss member 14B, and the end surface 26B thereof that faces the circuit substrate 4 may be oblique with respect to a central axis depending on the oblique angle of the circuit substrate 4 in the above seventh aspect.

With the above structure, the circuit substrate can be oblique with respect to the back surface of the display panel.

The display device 1, 1A, 1C according to a tenth aspect of the present disclosure may further include the oblique member 27 that has the tapped hole that is used to mount the circuit substrate 4 and that extends along the central axis, the end surface 28 thereof that faces the circuit substrate 4 being oblique with respect to the central axis depending on the oblique angle of the circuit substrate 4, the oblique member being disposed on the boss member 14A in the above seventh aspect.

With the above structure, the circuit substrate can be oblique with respect to the back surface of the display panel.

The present disclosure is not limited to the above embodiments. Various modifications can be made within the scope of Claims. The technical scope of the present disclosure also includes an embodiment that is obtained by appropriately combining technical means disclosed according to the different embodiments. A new technical feature can be obtained by combining the technical means disclosed according to the embodiments.

The present disclosure contains subject matter related to that disclosed in U.S. Provisional Patent Application No. 62/981,764 filed in the US Patent Office on Feb. 26, 2020, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
a display panel that displays an image;
a housing that contains the display panel; and
a circuit substrate that includes a circuit component relative to an image signal corresponding to the image that is displayed by the display panel and that faces a back surface of the display panel,
wherein the housing has a lower air vent that is formed below the circuit substrate and an upper air vent that is formed above the circuit substrate,
wherein a flow path for an airstream that flows from the lower air vent toward the upper air vent along the circuit substrate, based on generated heat from the circuit component is defined so as to face the back surface of the display panel in the housing, and
wherein the flow path is defined such that a sectional area of the flow path varies along the circuit substrate.

2. The display device according to claim 1, wherein the circuit substrate is oblique with respect to the back surface of the display panel.

3. The display device according to claim 2, wherein the circuit substrate is oblique such that a distance between a portion of the circuit substrate that faces the lower air vent and the back surface of the display panel is shorter than a distance between a portion of the circuit substrate that faces the upper air vent and the back surface of the display panel.

4. The display device according to claim 2, wherein an oblique angle of the circuit substrate with respect to the back surface of the display panel is no less than 3 degrees and no more than 7 degrees.

5. The display device according to claim 1, wherein a back wall of the housing that faces the back surface of the display panel is oblique with respect to the back surface of the display panel.

6. The display device according to claim 5, wherein the back wall is formed such that the flow path becomes narrower as a position is closer to the upper air vent from the lower air vent along the circuit substrate.

7. The display device according to claim 2, further comprising: a support chassis that supports the display panel and that faces the back surface of the display panel; and
a boss member that supports the circuit substrate and that faces a surface of the support chassis opposite the display panel.

8. The display device according to claim 7, wherein the boss member has a tapped hole that is used to mount the circuit substrate on the boss member and that extends along a central axis, and an end surface thereof that faces the support chassis is oblique with respect to the central axis depending on an oblique angle of the circuit substrate.

9. The display device according to claim 7, wherein the boss member has a tapped hole that is used to mount the circuit substrate on the boss member, and an end surface thereof that faces the circuit substrate is oblique with respect to a central axis depending on an oblique angle of the circuit substrate.

10. The display device according to claim 7, further comprising: an oblique member that has a tapped hole that is used to mount the circuit substrate and that extends along a central axis, an end surface thereof that faces the circuit substrate being oblique with respect to the central axis depending on an oblique angle of the circuit substrate, the oblique member being disposed on the boss member.
